(19) United States
(12) Patent Application Publication
(10) Pub. No.: US 2021/0313734 A1
(43) Pub. Date: Oct. 7, 2021

(54) ELECTRONIC APPARATUS

(71) Applicant: SHARP KABUSHIKI KAISHA, Osaka (JP)

(72) Inventors: MOTOO GOHDA, Osaka (JP); KAZUTAKA OKUZAKO, Osaka (JP); HIDETO OHHORI, Osaka (JP); YOSHIKAZU TAKEMOTO, Osaka (JP)

(21) Appl. No.: 17/219,393

(22) Filed: Mar. 31, 2021

(30) Foreign Application Priority Data
Apr. 7, 2020 (JP) 2020-069226

(51) Int. Cl. H01R 13/52; H01R 24/60; H05K 5/06

(52) U.S. Cl. CPC H01R 13/52; H05K 5/065; H01R 24/60

(57) ABSTRACT

An electronic apparatus includes a housing, a terminal component, and a waterproofing member. The housing is located a hole penetrating from an inner wall surface of the housing through an outer wall surface of the housing. The terminal component includes a contact that comes into electrical contact with a plug connector connected from outside the housing, and a stepped portion engaged in the inner wall surface from inside the housing. The terminal component is inserted in the hole. The waterproofing member is disposed in at least one of a first space and a second space. The first space is located between the inner wall surface and the stepped portion. The second space is located between an edge of the hole of the housing and an inserted portion of the terminal component, the inserted portion being inserted in the hole.

### CROSS-REFERENCE TO RELATED APPLICATION

The present application claims priority from Japanese Application JP2020-069226, the content of which is hereby incorporated by reference into this application.

### BACKGROUND OF THE INVENTION

### Field of the Invention

The present invention relates to an electronic apparatus.

### Description of the Related Art

To establish electrical connection with an external apparatus or other things, a conventional electronic apparatus has a receptacle connector electrically connected to a plug connector external to the electronic apparatus. For instance, Japanese Patent No. 6543740 discloses an electronic apparatus that includes a receptacle connector. The receptacle connector has a terminal component including a contact electrically connected to a plug connector, and has a guide guiding the plug connector to the terminal component. The terminal component is inserted into the guide. The terminal component also includes the following: a housing retaining the contact; a waterproofing member tightly closing the space between the housing and guide; and a fastened portion fastened to a circuit board internal to the electronic apparatus. The circuit board to which the fastened portion is fastened is parallel to a direction into which the terminal component is inserted. The fastened portion is perpendicularly fastened to the circuit board using a fastener, such as a screw.

### SUMMARY OF THE INVENTION

In such a conventional technique, the space between the housing and guide is tightly closed by pressing, with the housing and guide, the waterproofing member in a direction perpendicular to the direction into which the terminal component is inserted (hereinafter, referred to as an insertion direction).

Hence, unfailing waterproofing using the waterproofing member requires accurate placement of the terminal component and guide in the direction perpendicular to the insertion direction (hereinafter, referred to as a perpendicular direction).

The terminal component is herein fastened perpendicularly to the circuit board by the fastened portion. The circuit board is parallel to the insertion direction; placement with an accuracy required for the waterproofness of the waterproofing member needs strict positioning of the guide, circuit board, fastened portion, and other components in the perpendicular direction. Accordingly, failure to place, with sufficient accuracy, the guide, circuit board, fastened portion, and other components in the perpendicular direction can reduce the waterproofness of the electronic apparatus.

It is an object of one aspect of the present invention to offer an electronic apparatus that easily achieves high waterproofness.

To solve the above problem, an electronic apparatus according to one aspect of the present invention includes the following: a housing with a hole penetrating from the inner wall surface of the housing through the outer wall surface of the housing; a terminal component including a contact that comes into electrical contact with a plug connector connected from outside the housing, and a stepped portion engaged in the inner wall surface from inside the housing, the terminal component being inserted in the hole; and a waterproofing member disposed in at least one of (1) a first space located between the inner wall surface and the stepped portion, and (2) a second space located between the edge of the hole of the housing and an inserted portion of the terminal component, the inserted portion being inserted in the hole.

In this configuration, the terminal component includes the stepped portion engaged in the inner wall surface of the housing. Thus, inserting the terminal component from inside the electronic apparatus into the hole of the housing brings the stepped portion into engagement with the inner wall surface of the housing. At this time, the waterproofing member in at least one of the first and second spaces causes the terminal component to be positioned in a direction perpendicular to a direction into which the terminal component is inserted. The terminal component and housing press the waterproofing member, so that the waterproofing member tightly closes the space between the terminal component and housing. This facilitates waterproofness enhancement in the electronic apparatus.

The aspect of the present invention can offer an electronic apparatus that easily achieves high waterproofness.

### BRIEF DESCRIPTION OF THE DRAWINGS

FIG. 1 is a perspective view of the appearance of an electronic apparatus according to a first preferred embodiment of the present invention;

FIG. 2 is a sectional view of the electronic apparatus taken along line II-II in FIG. 1;

FIG. 3 is an exploded perspective view of main components of the electronic apparatus shown in FIG. 2;

FIG. 4 is a perspective view of a terminal component shown in FIG. 3, fastened to a partition wall;

FIG. 5 illustrates the lower surface of a terminal component according to a second preferred embodiment;

FIG. 6 is a sectional view of an electronic apparatus according to a third preferred embodiment;

FIG. 7 is an exploded perspective view of main components of the electronic apparatus shown in FIG. 6; and

FIG. 8 illustrates the lower surface of the terminal component shown in FIG. 7.

### DETAILED DESCRIPTION OF THE INVENTION

### First Preferred Embodiment

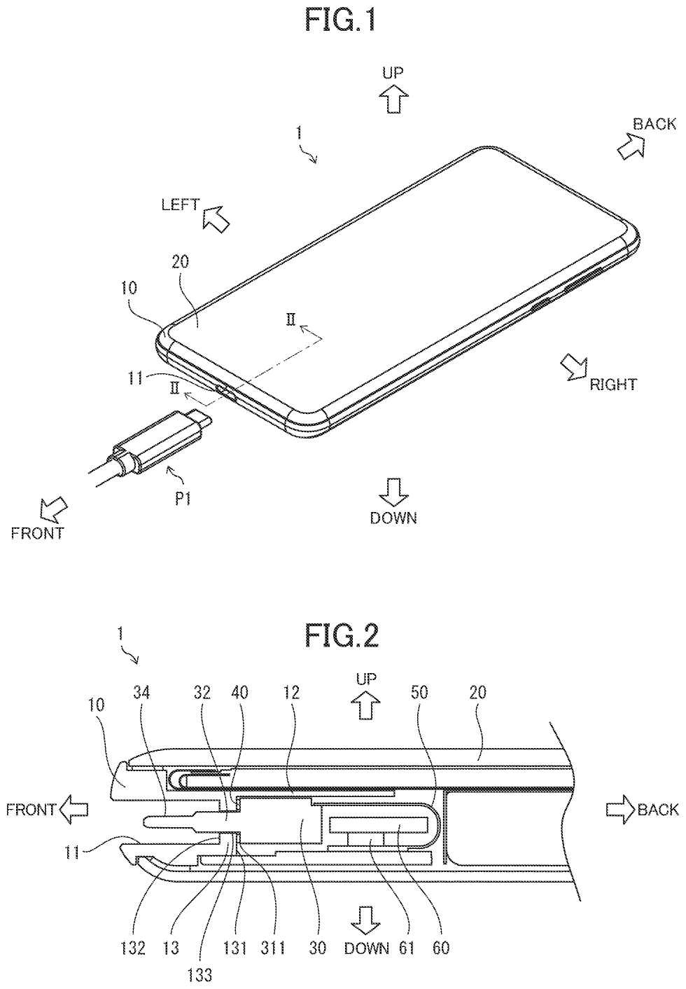

A first preferred embodiment of the present invention will be detailed. FIG. 1 is a perspective view of the appearance of an electronic apparatus 1 according to this preferred embodiment. Although in this preferred embodiment, the electronic apparatus 1 is a smartphone, as illustrated in FIG. 1, the electronic apparatus 1 may be any apparatus. For instance, the electronic apparatus 1 may be a mobile phone, a tablet terminal, a portable game machine, or other things.

The electronic apparatus 1 includes a housing 10 and a display unit 20. The housing 10 supports electronic components and other things disposed inside the electronic apparatus 1. The housing 10 includes an insertion portion 11 for inserting a plug connector P1 connected to the electronic apparatus 1 from outside the housing 10. The plug connector P1 complies with the universal-serious-bus (USB) standard or high-definition-multimedia-interface (HDMI; registered trademark) standard. The electronic apparatus 1, when connected to the plug connector P1, can be electrically connected to an external apparatus (not shown), such as an external power source.

The display unit 20 displays various images. Examples of the display unit 20 include a liquid crystal display, an organic electroluminescence (EL) display, and an inorganic EL display. The display unit 20 may be a touch panel that detects the position of a user touch. The display unit 20 is a substantially rectangular plate and is supported by the housing 10.

In the Specification, a direction where the display unit 20 is located with reference to the housing 10 is referred to as an upward direction, and a direction where the housing 10 is located with reference to the display unit 20 is referred to as a downward direction. Furthermore, a direction where the insertion portion 11 is disposed in the housing 10 is referred to as a forward direction, and a direction opposite to the forward direction is referred to as a backward direction Furthermore, directions on the left and right sides of the electronic apparatus 1 oriented from the forward to backward directions with the upper part of the electronic apparatus 1 upward and the lower part of the same downward are respectively referred to as a leftward direction and a rightward direction.

FIG. 2 is a sectional view of the electronic apparatus 1 taken along line II-II in FIG. 1. In addition to the housing 10 and display unit 20, the electronic apparatus 1 includes a terminal component 30, a first waterproofing member (waterproofing member) 40, a conductive plate 50, a circuit board 60, and a connector 61, as illustrated in FIG. 2.

The housing 10 includes a plate 12 and a partition wall 13 in addition to the insertion portion 11. The plate 12 extends in the back-and-forth and side-to-side directions, and has an upper surface by which the display unit 20 is supported. At the rear of the insertion portion 11, the partition wall 13 sections the interior and exterior of the housing 10. The rear of the partition wall 13 is the interior of the housing 10, and the front of the partition wall 13 is the exterior of the housing 10. In other words, the rear surface of the partition wall 13 is an inner wall surface 131, and the front surface of the same is an outer wall surface 132.

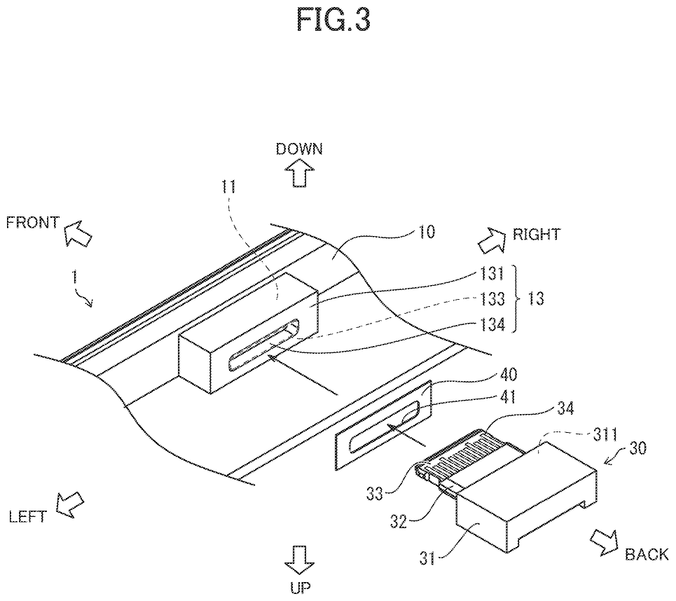

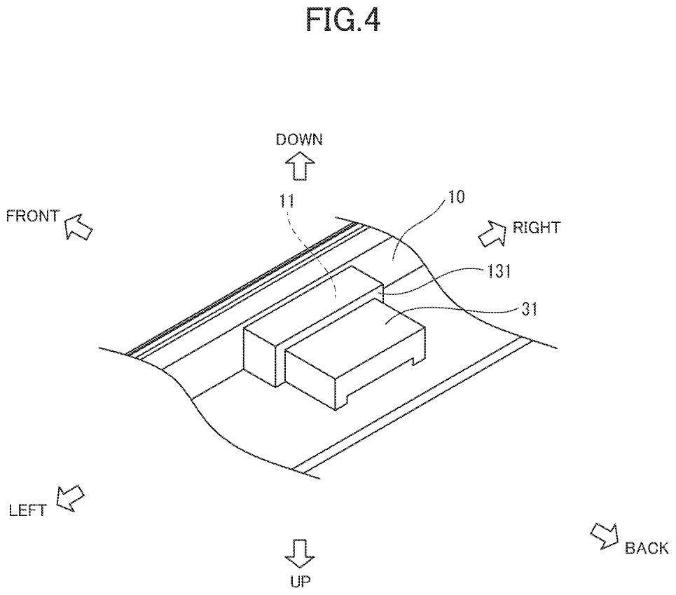

FIG. 3 is an exploded perspective view of main components of the electronic apparatus 1 shown in FIG. 2. FIG. 4 is a perspective view of the terminal component 30 shown in FIG. 3, fastened to the partition wall 13. The partition wall 13 has a wall hole 133 disposed near its middle in the up-and-down direction and penetrating the partition wall 13 in the back-and-forth direction from the inner wall surface 131 through the outer wall surface 132, as illustrated in FIGS. 2 to 4. The terminal component 30 is inserted into the wall hole 133 from the backward direction to the forward direction. In the following description, the edge of the wall hole 133 of the partition wall 13 is referred to as a hole edge 134.

The direction in which the terminal component 30 is inserted into the wall hole 133 is not limited to the example illustrated in FIGS. 2 to 4. For instance, the terminal component 30 may be flipped vertically and then inserted into the wall hole 133. The conductive plate 50 in this case may extend backward from the lower part at the rear of a body 31 of the terminal component 30.

The terminal component 30 includes the body 31, a first protrusion (inserted portion) 32, a second protrusion 33, and a contact 34. Each of the body 31, first protrusion 32, and second protrusion 33 has a substantial-rectangular-parallelepiped shape and establishes conduction between the contact 34 and conductive plate 50. The body 31 in the up-and-down direction is longer than the wall hole 133 in the up-and-down direction. The body 31 in the side-to-side direction is longer than the wall hole 133 in the side-to-side direction.

The first protrusion 32 protrudes forward from near the middle in the up-and-down and side-to-side directions on the front surface of the body 31. The first protrusion 32 is inserted into the wall hole 133. The first protrusion 32 in the up-and-down direction is as long as or slightly shorter than the wall hole 133 in the up-and-down direction. The first protrusion 32 in the side-to-side direction is as long as or slightly shorter than the wall hole 133 in the side-to-side direction. The first protrusion 32 in the back-and-forth direction is longer than the partition wall 13 in the back-and-forth direction; that is, the length of the first protrusion 32 in the back-and-forth direction is greater than the thickness of the partition wall 13.

At least part of the hole edge 134 can come into contact with the first protrusion 32 when the first protrusion 32 is inserted in the wall hole 133. In this case, the housing 10 can retain the terminal component 30 more firmly. The surfaces of the hole edge 134 and first protrusion 32 are preferably in contact with each other in order for the housing 10 to retain the terminal component 30 further firmly.

The body 31 has, on its front surface, a stepped surface (stepped portion) 311 disposed in a region where the first protrusion 32 does not protrude. The stepped surface 311 is oriented forward and faces the inner wall surface 131. The stepped surface 311 is in engagement with the inner wall surface 131 from the rear (interior) of the housing 10 when the first protrusion 32 is inserted in the wall hole 133.

The second protrusion 33 protrudes forward from near the middle in the up-and-down and side-to-side directions on the front surface of the first protrusion 32. The second protrusion 33 in the up-and-down direction is shorter than the first protrusion 32 in the up-and-down direction. The second protrusion 33 in the side-to-side direction is shorter than the first protrusion 32 in the side-to-side direction.

The contact 34 is disposed on the upper and lower surfaces of the second protrusion 33. The contact 34 comes into electrical contact with the plug connector P1 (shown in FIG. 1), thus enabling the electronic apparatus 1 to be electrically connected to an external apparatus. The shapes and dimensions of the insertion portion 11, first protrusion 32, second protrusion 33 and contact 34 are set to conform to the plug connector P1, and comply with, for instance, the USB standard or HDMI (registered trademark) standard.

The first waterproofing member 40 is disposed in a first space located between the inner wall surface 131 and stepped surface 311. Accordingly, the stepped surface 311 is brought into indirect engagement with the inner wall surface 131 from inside the housing 10 via the first waterproofing member 40. The first waterproofing member 40 is, but not limited to, a double-sided adhesive tape that bonds the inner wall surface 131 and stepped surface 311 together. For instance, the first waterproofing member 40 may be an adhesive that surrounds the wall hole 133, and bonds the inner wall surface 131 and stepped surface 311 together.

The first waterproofing member 40 has a waterproofing hole 41 penetrating in the back-and-forth direction. The waterproofing hole 41 in the up-and-down direction is as long as or longer than the wall hole 133 in the up-and-down direction. The waterproofing hole 41 in the side-to-side direction is as long as or longer than the wall hole 133 in the side-to-side direction. The waterproofing hole 41 receives the first protrusion 32.

The first waterproofing member 40 is elastic. Upon the first protrusion 32 being inserted into the wall hole 133, the first waterproofing member 40 is pressed forward by the stepped surface 311 and pressed backward by the inner wall surface 131. The first waterproofing member 40 thus tightly closes the space between the stepped surface 311 and inner wall surface 131. The first waterproofing member 40 can consequently prevent moisture from entering the housing 10 from outside via the wall hole 133 and coming into contact with the circuit board 60. In addition, the first waterproofing member 40 can position and fix, to the housing 10, the terminal component 30 positioned in the up-and-down and side-to-side directions (directions perpendicular to the insertion direction of the terminal component 30) by the hole edge 134 and inner wall surface 131.

The conductive plate 50 extends backward from the upper part at the rear of the body 31 of the terminal component 30. The conductive plate 50 is bent at its rear so as to protrude in the backward direction, and is connected to the circuit board 60 via the connector 61. The conductive plate 50 establishes conduction between the terminal component 30 and circuit board 60.

The circuit board 60 includes a circuit (not shown) that operates the electronic apparatus 1. The circuit board 60 and conductive plate 50 may be connected together via the connector 61 for instance; alternatively, they may be connected together using surface mount technology (SMT), which is not shown. The circuit board 60 and conductive plate 50 are connected together by any electrically connected means.

In the foregoing configuration, the terminal component 30 has the stepped surface 311 that is brought into engagement with the inner wall surface 131 of the housing 10. Hence, inserting the terminal component 30 into the wall hole 133 of the housing 10 from inside the electronic apparatus 1 brings the stepped surface 311 into engagement with the inner wall surface 131 of the housing 10. The terminal component 30 is accordingly positioned in the up-and-down and side-to-side directions by the hole edge 134 and inner wall surface 131. At this time, the first waterproofing member 40 in the first space between the inner wall surface 131 and stepped surface 311 bonds the inner wall surface 131 and stepped surface 311 together, thus positioning and fixing the terminal component 30 to the housing 10. Furthermore, the terminal component 30 and housing 10 press the first waterproofing member 40, so that the first waterproofing member 40 tightly closes the space between the terminal component 30 and housing 10. This facilitates waterproofness enhancement in the electronic apparatus 1.

The first waterproofing member 40 bonds the inner wall surface 131 and stepped surface 311 together, thus enabling the terminal component 30 to be positioned in the up-and-down and side-to-side directions more accurately. Furthermore, fixing the terminal component 30 requires no element such as the fastened portion disclosed in Japanese Patent No. 6543740, thereby achieving size reduction of the terminal component 30. The electronic apparatus 1 can be consequently thin or small.

Modification

Although having a substantial-rectangular-parallelepiped shape in this preferred embodiment, each of the body 31, first protrusion 32, and second protrusion 33 may have any shape. For instance, each side and each corner of the body 31 may be rounded. To be specific, the left surface of the body 31 may be bent so as to protrude in the leftward direction, and the right surface of the same may be bent so as to protrude in the rightward direction. Further, each side and each corner of the first protrusion 32, and each side and each corner of the second protrusion 33 may be rounded in accordance with a standard with which the plug connector P1 complies.

### Second Preferred Embodiment

A second preferred embodiment of the present invention will be detailed. For convenience in description, components having the same functions as those described in the foregoing preferred embodiment will be denoted by the same signs and will not be elaborated upon here. The second preferred embodiment is different from the first preferred embodiment in that a terminal component 301 includes a first protrusion (inserted portion) 321 having a plurality of projections 322.

FIG. 5 illustrates the lower surface of the terminal component 301 according to this preferred embodiment. The terminal component 301 includes the body 31, the first protrusion (inserted portion) 321, the second protrusion 33, and the contact 34. The first protrusion 321 has the plurality of projections 322.

In the example of FIG. 5, the projections 322 are disposed at three locations on the lower surface of the first protrusion 321, at one location on the right surface of the same, and at one location on the left surface of the same. Any number of projections 322 may be provided; for instance, the projections 322 may be disposed at two or less locations on the lower surface of the first protrusion 321, or at four or more locations on the lower surface of the same. The projections 322 are spaced away from one another in the side-to-side direction at substantially regular intervals. In some preferred embodiments, the upper surface (not shown) of the first protrusion 321 may have a plurality of projections (not shown) arranged so as to longitudinally symmetrical to the projections 322 disposed on the lower surface of the first protrusion 321.

In this configuration, the first protrusion 321 has the plurality of projections 322, thereby reducing the area of contact between the hole edge 134 (not shown in FIG. 5) and first protrusion 321 when compared to a configuration where no projections 322 are provided. This can reduce the friction between the hole edge 134 and first protrusion 321 when the terminal component 301 is inserted into the wall hole 133 of the housing 10. Consequently, the gap between the hole edge 134 and terminal component 301 can be reduced, enabling the terminal component 301 to be positioned further accurately. This improves the workability of manufacturing the electronic apparatus 1, thus enabling the electronic apparatus 1 to be manufactured more efficiently.

To reduce the friction between the hole edge 134 and first protrusion 321, the hole edge 134 and projections 322 are preferably in line contact with each other rather than in surface contact with each other, and they are further preferably in point contact with each other. In this case, the area of contact between the hole edge 134 and projections 322 tends to decrease in the order of surface contact, line contact, and point contact. For this reason, the friction between the hole edge 134 and first protrusion 321 can be further reduced when the terminal component 301 is inserted into the wall hole 133 (not shown in FIG. 5) of the housing 10 (not shown in FIG. 5). The gap between the hole edge 134 and terminal component 301 can be consequently reduced, enabling the terminal component 301 to be positioned further accurately. This improves the workability of manufacturing the electronic apparatus 1, thus enabling the electronic apparatus 1 to be manufactured further efficiently.

Modification

Although the first protrusion 321 has the projections 322 in this preferred embodiment, the present invention is not limited to this configuration. For instance, not the first protrusion 321, but the hole edge 134 may have a plurality of projections (not shown). Alternatively, the first protrusion 321 and the hole edge 134 both may have a plurality of projections.

### Third Preferred Embodiment

A third preferred embodiment of the present invention will be detailed. For convenience in description, components having the same functions as those described in the foregoing preferred embodiments will be denoted by the same signs and will not be elaborated upon here. The third preferred embodiment is different from the first preferred embodiment in that an electronic apparatus 2 includes a second waterproofing member 70.

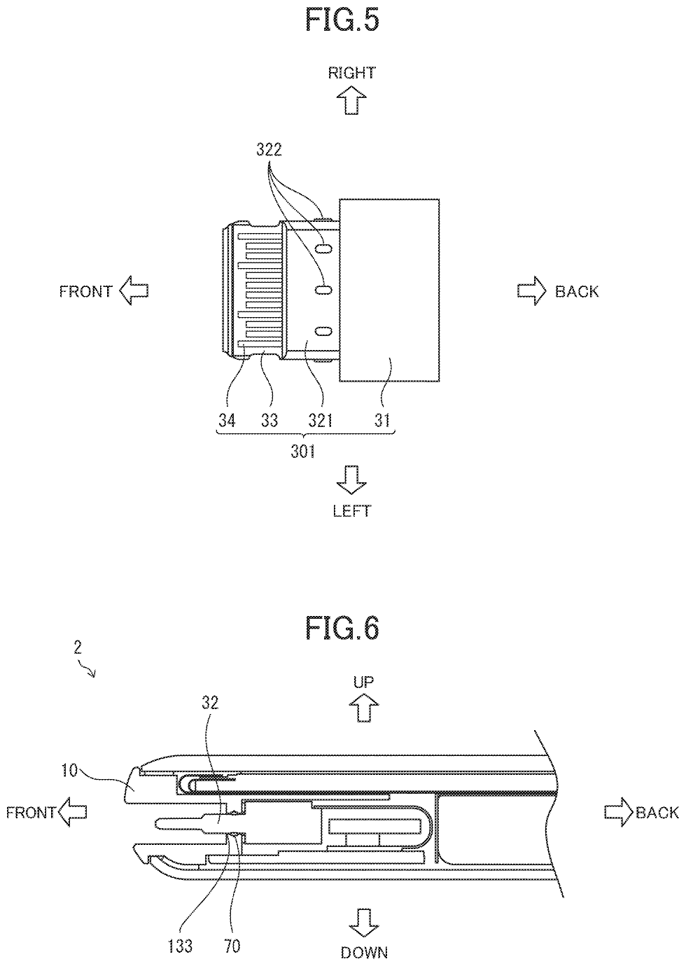

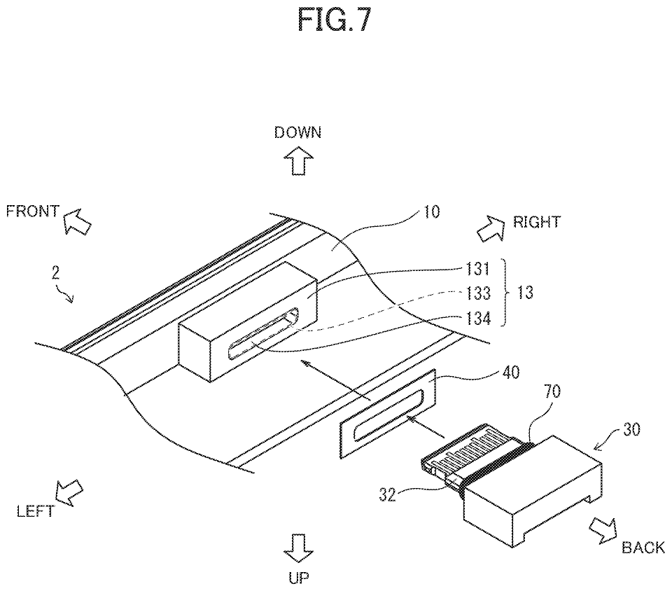

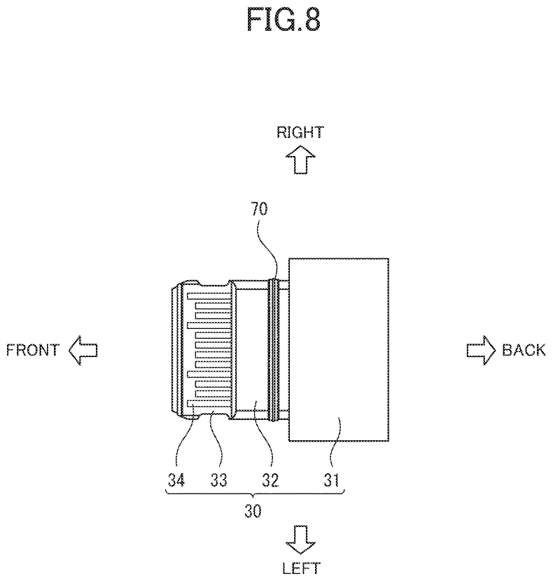

FIG. 6 is a sectional view of the electronic apparatus 2 according to the third preferred embodiment. FIG. 7 is an exploded perspective view of main components of the electronic apparatus 2 shown in FIG. 6. FIG. 8 illustrates the lower surface of the terminal component 30 shown in FIG. 7. As illustrated in FIGS. 6 to 8, the second waterproofing member 70 firmly closes the space between the hole edge 134 and first protrusion 32. The second waterproofing member 70 is, but not limited to, an elastic circular resin gasket. The second waterproofing member 70 is preferably made of low-adhesion material so that the terminal component 30 can be easily inserted into the wall hole 133.

As illustrated in FIG. 7, inserting the first protrusion 32 into the wall hole 133, with the second waterproofing member 70 attached to the rear of the first protrusion 32 enables the second waterproofing member 70 to be placed between the hole edge 134 and first protrusion 32. In some preferred embodiments, the second waterproofing member 70 may be placed between the hole edge 134 and first protrusion 32 by inserting the first protrusion 32 into the wall hole 133, with the second waterproofing member 70 attached to the hole edge 134. Further, the second waterproofing member 70 may be molded in a manner integral with the first protrusion 32 or partition wall 13. Alternatively, the second waterproofing member 70 may be produced in a manner separate from the terminal component 30 and partition wall 13, and may be then attached to the first protrusion 32 or hole edge 134.

In the above configuration, the second waterproofing member 70 is disposed in a second space located between the hole edge 134 and first protrusion 32. The second waterproofing member 70 enables the first protrusion 32 to be positioned in substantially the middle of the wall hole 133 in the up-and-down and side-to-side directions, and the second waterproofing member 70 can appropriately exert its waterproofness. This facilitates waterproofness enhancement in the electronic apparatus 2.

Modification

In this preferred embodiment, the electronic apparatus 2 includes both of the first waterproofing member 40 and second waterproofing member 70 by way of example. In some preferred embodiments, the electronic apparatus 2 may include not the first waterproofing member 40, but the second waterproofing member 70. The stepped surface 311 in this case is in direct engagement with the inner wall surface 131 from inside the housing 10.

When the electronic apparatus 2 includes not the first waterproofing member 40, but the second waterproofing member 70, the inner wall surface 131 and stepped surface 311 may be in surface contact with each other. The inner wall surface 131 in this case enables the stepped surface 311 to be more accurately positioned in the back-and-forth direction. Consequently, the terminal component 30 can be more accurately positioned in the back-and-forth direction.

In some preferred embodiments, one or both of the hole edge 134 and first protrusion 32 may have a groove (not shown) for housing at least part of the second waterproofing member 70. This groove can be formed through integral molding. In this case, the second waterproofing member 70 can be more accurately positioned between the hole edge 134 and first protrusion 32.

### SUMMARY

The electronic apparatus 1 or 2 according to a first aspect of the present invention includes the following: the housing 10 with a hole (wall hole 133) penetrating from the inner wall surface 131 of the housing 10 through the outer wall surface 132 of the housing 10; the terminal component 30 including the contact 34 that comes into electrical contact with the plug connector P1 connected from outside the housing 10, and a stepped portion (stepped surface 311) engaged in the inner wall surface 131 from inside the housing 10, the terminal component 30 being inserted in the hole (wall hole 133); and a waterproofing member (first waterproofing member 40 or second waterproofing member 70) disposed in at least one of (1) a first space located between the inner wall surface 131 and the stepped portion (stepped surface 311), and (2) a second space located between the edge (hole edge 134) of the hole (wall hole 133) of the housing 10 and an inserted portion (first protrusion 32) of the terminal component 30, the inserted portion (first protrusion 32) being inserted in the hole (wall hole 133).

In this configuration, the terminal component 30 includes the stepped portion (stepped surface 311) engaged in the inner wall surface 131 of the housing 10. Thus, inserting the terminal component 30 from inside the electronic apparatus 1 or 2 into the hole (wall hole 133) of the housing 10 brings the stepped portion (stepped surface 311) into engagement with the inner wall surface 131 of the housing 10. As a result, the hole edge 134 and inner wall surface 131 cause the terminal component 30 or 301 to be positioned in directions (up-and-down and side-to-side directions) perpendicular to the insertion direction. At this time, the waterproofing member (first waterproofing member 40 or second waterproofing member 70) in at least one of the first and second spaces causes the terminal component 30 to be positioned and fixed in the directions perpendicular to the insertion direction. Furthermore, the terminal component 30 and housing 10 press the waterproofing member (first waterproofing member 40 or second waterproofing member 70), so that the waterproofing member (first waterproofing member 40 or second waterproofing member 70) tightly bonds the space between the terminal component 30 and housing 10. This facilitates waterproofness enhancement in the electronic apparatus 1 or 2.

In the first aspect, the electronic apparatus 1 or 2 according to a second aspect may be configured such that the waterproofing member (first waterproofing member 40 or second waterproofing member 70) joins the inner wall surface 131 and the stepped portion (stepped surface 311) together. In this configuration, the waterproofing member (first waterproofing member 40 or second waterproofing member 70) joins the inner wall surface 131 and stepped portion (stepped surface 311) together, thereby enabling the terminal component 30 to be more accurately positioned and fixed in the directions perpendicular to the insertion direction of the terminal component 30.

In the first or second aspect, the electronic apparatus 1 or 2 according to a third aspect of the present invention may be configured such that the edge (hole edge 134) is at least partly in contact with the terminal component 30. In this configuration, the edge (hole edge 134) is at least partly in contact with the terminal component 30, thereby enabling the housing 10 to retain the terminal component 30 more firmly.

In any of the first to third aspects, the electronic apparatus 1 or 2 according to a fourth aspect of the present invention may be configured such that the edge (hole edge 134) and the inserted portion (first protrusion 32) are in surface contact with each other. In this configuration, the surfaces of the edge (hole edge 134) and inserted portion (first protrusion 32) are in contact with each other, thereby enabling the housing 10 to retain the terminal component 30 further firmly.

In any of the first to third aspects, the electronic apparatus 1 or 2 according to a fifth aspect of the present invention may be configured such that at least one of the edge (hole edge 134) and the inserted portion (first protrusion 32 or 321) includes a plurality of projections.

In this configuration, one of the edge (hole edge 134) and inserted portion (first protrusion 32 or 321) includes a plurality of projections, thereby reducing the area of contact between the edge (hole edge 134) and inserted portion (first protrusion 32 or 321) when compared to a configuration where no projections 322 are provided. The friction between the edge (hole edge 134) and inserted portion (first protrusion 32 or 321) can be thus reduced when the terminal component 30 or 301 is inserted into the hole (wall hole 133) of the housing 10. Consequently, the gap between the edge (hole edge 134) and terminal component 30 or 301 can be reduced, enabling the terminal component 30 or 301 to be positioned further accurately. This improves the workability of manufacturing the electronic apparatus 1 or 2, thus enabling the electronic apparatus 1 or 2 to be manufactured more efficiently.

In the first aspect, the electronic apparatus 2 according to a sixth aspect of the present invention may be configured such that the second waterproofing member 70 is disposed in the second space, and that the inner wall surface 131 and the stepped portion (stepped surface 311) are in surface contact with each other. In this configuration, the inner wall surface 131 enables the stepped portion (stepped surface 311) to be more accurately positioned in the back-and-forth direction. Consequently, the terminal component 30 can be more accurately positioned in the back-and-forth direction.

While there have been described what are at present considered to be certain embodiments of the invention, it will be understood that various modifications may be made thereto, and it is intended that the appended claim cover all such modifications as fall within the true spirit and scope of the invention.

What is claimed is:

1. An electronic apparatus comprising:
a housing with a hole penetrating from an inner wall surface of the housing through an outer wall surface of the housing;
a terminal component including
a contact that comes into electrical contact with a plug connector connected from outside the housing, and
a stepped portion engaged in the inner wall surface from inside the housing,
the terminal component being inserted in the hole; and
a waterproofing member disposed in at least one of (1) a first space located between the inner wall surface and the stepped portion, and (2) a second space located between an edge of the hole of the housing and an inserted portion of the terminal component, the inserted portion being inserted in the hole.

2. The electronic apparatus according to claim 1, wherein the waterproofing member joins the inner wall surface and the stepped portion together.

3. The electronic apparatus according to claim 1, wherein the edge is at least partly in contact with the terminal component.

4. The electronic apparatus according to claim 1, wherein the edge and the inserted portion are in surface contact with each other.

5. The electronic apparatus according to claim 1, wherein at least one of the edge and the inserted portion includes a plurality of projections.

6. The electronic apparatus according to claim 1, wherein
the waterproofing member is disposed in the second space, and
the inner wall surface and the stepped portion are in surface contact with each other.
